(19) United States
(12) Patent Application Publication
(10) Pub. No.: US 2017/0154905 A1
(43) Pub. Date: Jun. 1, 2017

(54) THIN FILM TRANSISTOR AND PREPARATION METHOD THEREOF, ARRAY SUBSTRATE, AND DISPLAY PANEL

(71) Applicants: BOE TECHNOLOGY GROUP CO., LTD., Beijing (CN); SOUTH CHINA UNIVERSITY OF TECHNOLOGY, Guangzhou, Guangdong (CN)

(72) Inventors: Guangcai Yuan, Beijing (CN); Liangchen Yan, Beijing (CN); Xiaoguang Xu, Beijing (CN); Lei Wang, Guangzhou, Guangdong (CN); Junbiao Peng, Guangzhou, Guangdong (CN); Linfeng Lan, Guangzhou, Guangdong (CN)

(21) Appl. No.: 15/122,155

(22) PCT Filed: Oct. 9, 2015
(86) PCT No.: PCT/CN2015/091540

§ 371 Date: Aug. 26, 2016

(30) Foreign Application Priority Data
May 8, 2015 (CN) 201510232985.5

(51) Int. Cl. H01L 27/12; H01L 29/49; H01L 29/10; H01L 29/423; H01L 21/324; H01L 29/66; H01L 29/417; H01L 29/786; H01L 21/3213

(52) U.S. Cl. CPC H01L 27/1288; H01L 29/78618; H01L 29/4908; H01L 29/1079; H01L 21/32139; H01L 21/324; H01L 29/66742; H01L 29/41733; H01L 29/42384; H01L 21/32133; H01L 27/1248

(57) ABSTRACT

This disclosure provides a thin film transistor and the preparation method thereof, an array substrate, and a display panel, so as to solve the problem that the active layer is prone to be corroded when a metal oxide thin film transistor is produced by a back channel etching process. The preparation method comprises: forming a gate electrode metal thin film on a base substrate, and allowing the gate electrode metal thin film to form a gate electrode metal layer comprising a gate electrode by a patterning process; forming a gate electrode insulating layer on the gate electrode metal layer; forming an active layer on the gate electrode insulating layer; preparing a metal nanoparticle layer on the active layer, said metal nanoparticle layer being used as an etching protection layer; forming a source and drain electrode metal thin film on the base substrate on which the above processes are finished, and allowing the source and drain electrode metal thin film to form a source and drain electrode metal layer comprising a source electrode and a drain electrode by a patterning process, wherein the source electrode and the drain electrode cover a part of the metal nanoparticle layer; removing or oxidizing the part of the metal nanoparticle layer which is not covered by the source electrode and the drain electrode in an oxygen-containing atmosphere; and forming a passivation layer on the source and drain electrode metal layer.

### TECHNICAL FIELD

This disclosure relates to the technical field of semiconductors, and particularly to a thin film transistor and the preparation method thereof, an array substrate, and a display panel.

### BACKGROUND ART

Flat panel displays (FPD) have become mainstream products in the market, and the types of flat panel displays are more and more, such as liquid crystal displays(LCDs), organic light-emitting diode (OLED) displays, plasma display panels (PDPs), field emission displays (FEDs), etc.

The thin film transistor (TFT) back panel technology, as the core technology in FPD industry, is also experiencing deep revolution. In particular, with respect to metal oxide thin film transistors (MOTFTs), because of the characteristics of high mobility (approximately 5 to 50 centimeter²/volt·second), simple manufacture process, relatively low cost, excellent large-area uniformity, etc., the MOTFT technology has attracted a large number of attentions since it brought out.

At present, the structures mainly used in MOTFTs include a back channel etching structure and an etching barrier layer structure. Since the MOTFT of back channel etching structure has a relatively simple manufacture process which is the same as the conventional manufacture process of amorphous silicon and has relatively low equipment investment and production cost, it is considered to be the necessary development direction in which the large-scale mass production and wide utilization of MOTFTs are achieved. In a MOTFT of back channel etching structure, after an active layer is generated, a metal layer is deposited on the active layer and is patterned into a source electrode and a drain electrode. As for an etching barrier layer structure, after an active layer is generated, an etching barrier layer is first produced, and then a metal layer is deposited thereon and is patterned into a source electrode and a drain electrode. However, when the source electrode and the drain electrode are etched on the active layer, the problem of the active layer being corroded, i.e., damage of MOTFT back channel, will occur by using either dry etching or wet etching. For example, when dry etching is used, the active layer composed of metal oxide is prone to be damaged by ions, such that carrier traps are generated on the surface of exposed channels and the concentration of oxygen vacancies increases, resulting in poor device stability. For further example, when wet etching is used, the active layer composed of metal oxide is relatively sensitive to most acidic etching solutions and is prone to be corroded in the process of etching, such that the device performance will be greatly affected.

### SUMMARY

An object of this disclosure is to provide a thin film transistor and the preparation method thereof, an array substrate, and a display panel, so as to solve the problem in the prior art that the active layer is prone to be corroded when a metal oxide thin film transistor is produced by using a back channel etching process.

The object of this disclosure is achieved by the following technical solutions.

An embodiment of this disclosure provides a preparation method of a thin film transistor, comprising:

forming a gate electrode metal thin film on a base substrate, and allowing the gate electrode metal thin film to form a gate electrode metal layer comprising a gate electrode by a patterning process;

forming a gate electrode insulating layer on the gate electrode metal layer;

forming a metal oxide thin film on the gate electrode insulating layer, and allowing the metal oxide thin film to form a pattern of an active layer by a patterning process;

preparing a metal nanoparticle layer on the active layer, said metal nanoparticle layer being used as an etching protection layer;

forming a source and drain electrode metal thin film on the base substrate on which the above processes are finished, and allowing the source and drain electrode metal thin film to form a source and drain electrode metal layer comprising a source electrode and a drain electrode by a patterning process, wherein the source electrode and the drain electrode cover a part of the metal nanoparticle layer;

removing or oxidizing the part of the metal nanoparticle layer which is not covered by the source electrode and the drain electrode in an oxygen-containing atmosphere; and

forming a passivation layer on the source and drain electrode metal layer.

In this embodiment, by using the metal nanoparticle layer as a protection layer of the active layer, the active layer can be protected when the source electrode and the drain electrode are etched, so as to prevent device badness caused by the corrosion of the active layer; and at the meanwhile, the metal nanoparticle layer has a good conductivity and good thermal stability, and the requirements for the preparation process of the metal oxide thin film transistor are relatively low, such that the preparation of the metal oxide thin film transistor by a simple process and a low cost is achieved.

Preferably, the metal nanoparticle layer is prepared by using at least one material of gold nanoparticles, silver nanoparticles, platinum nanoparticles, beryllium nanoparticles, nickel nanoparticles, and cobalt nanoparticles. In this embodiment, the metal nanoparticle layer is prepared by using gold nanoparticles, silver nanoparticles, platinum nanoparticles, beryllium nanoparticles, nickel nanoparticles, cobalt nanoparticles, or the like, and the active layer can be protected when the source electrode and the drain electrode are subsequently etched, so as to prevent device badness caused by the corrosion of the active layer.

Preferably, the preparation of the metal nanoparticle layer on the active layer specifically comprises:

preparing the metal nanoparticle layer on the active layer by using a physical vapor deposition, a chemical vapor deposition, a hydrothermal method, a sol-gel method, a spray pyrolysis method, or a hot wall method.

Preferably, the metal nanoparticle layer is prepared in a thickness of 1 to 5 nanometers.

Preferably, removing or oxidizing the part of the metal nanoparticle layer which is not covered by the source electrode and the drain electrode is performed by using oxygen plasma.

Preferably, a glass substrate having a buffering layer is used as the base substrate.

Preferably, a flexible substrate having a water-oxygen barrier layer is used as the base substrate, and polyethylene naphthalate, polyethylene terephthalate, a polyimide, or a metal foil is used as the material of the flexible substrate.

Preferably, the gate electrode metal thin film is prepared by using a single film layer of any one of an aluminum thin film, a copper thin film, a molybdenum thin film, a titanium thin film, a silver thin film, a gold thin film, a tantalum thin film, a tungsten thin film, a chromium thin film, and an aluminum alloy thin film, or a composite film layer composed of at least two of the thin films, and the gate electrode metal thin film is prepared in a thickness of 100 to 2000 nanometers.

Preferably, the gate electrode insulating layer is prepared by using a monolayer of a silicon oxide thin film, a silicon nitride thin film, an aluminum oxide thin film, a tantalum pentoxide thin film, or an ytterbium oxide thin film, or the gate electrode insulating layer is prepared by using a composite thin film composed of at least two monolayers of the thin films, and the gate electrode insulating layer is prepared in a thickness of 50 to 500 nanometers.

Preferably, the active layer is prepared by using a metal oxide containing at least one of In, Zn, Ga, and Sn, and the active layer is prepared in a thickness of 10 to 200 nanometers.

Preferably, the source and drain electrode metal thin film is prepared by using a single film layer of any one of an aluminum thin film, a copper thin film, a molybdenum thin film, and a titanium thin film, or a composite film layer composed of at least two or more of the thin films, and the source and drain electrode metal thin film is prepared in a thickness of 100 to 2000 nanometers.

Preferably, the passivation layer may be a single film layer of any one of or a composite film layer composed of at least two or more of silicon oxide, silicon nitride, aluminum oxide, ytterbium oxide, polyimides, benzocyclobutene, or polymethyl methacrylate. Preferably, the passivation layer has a thickness of 50 to 2000 nanometers.

An embodiment of this disclosure provides a thin film transistor, comprising:

a base substrate;

a gate electrode metal layer formed on the base substrate, wherein the gate electrode metal layer comprises a gate electrode;

a gate electrode insulating layer formed on the gate electrode metal layer;

an active layer formed on the gate electrode insulating layer;

a metal nanoparticle layer formed on the active layer, wherein the metal nanoparticle layer is used as an etching protection layer;

a source and drain electrode metal layer formed on the metal nanoparticle layer, wherein the source and drain electrode metal layer comprises a source electrode and a drain electrode; and

a passivation layer formed on the source and drain electrode metal layer.

An embodiment of this disclosure provides an array substrate, comprising the thin film transistor as provided by the above embodiment.

An embodiment of this disclosure provides a display panel, comprising the array substrate as provided by the above embodiment.

The embodiments of this disclosure have the advantageous effects as follows. By using the metal nanoparticle layer as a protection layer of the active layer, the active layer may be protected when the source electrode and the drain electrode are etched, so as to prevent device badness caused by the corrosion of the active layer; and at the meanwhile, the metal nanoparticle layer has a good conductivity and good thermal stability, and the requirements for the preparation process of the metal oxide thin film transistor are relatively low, such that the preparation of the metal oxide thin film transistor by a simple process and a low cost is achieved.

### DESCRIPTION OF THE DRAWINGS

FIG. 1 is a flow chart of a preparation method of a metal oxide thin film transistor provided by an embodiment of this disclosure;

FIG. 2 is a structural schematic diagram of the metal oxide thin film transistor in which the gate electrode is prepared in an embodiment of this disclosure;

FIG. 3 is a structural schematic diagram of the metal oxide thin film transistor in which the gate electrode insulating layer is prepared in an embodiment of this disclosure;

FIG. 4 is a structural schematic diagram of the metal oxide thin film transistor in which the active layer is prepared in an embodiment of this disclosure;

FIG. 5 is a structural schematic diagram of the metal oxide thin film transistor in which the metal nanoparticle layer is prepared in an embodiment of this disclosure;

FIG. 6 is a structural schematic diagram of the metal oxide thin film transistor in which the source and drain electrode metal thin film is prepared in an embodiment of this disclosure;

FIG. 7 is a structural schematic diagram of the metal oxide thin film transistor in which the source electrode and the drain electrode are prepared in an embodiment of this disclosure;

FIG. 8 is a structural schematic diagram of the metal oxide thin film transistor in which the metal nanoparticle layer not covered by the source electrode and the drain electrode is removed in an embodiment of this disclosure;

FIG. 9 is a structural schematic diagram of the metal oxide thin film transistor in which the passivation layer is prepared in an embodiment of this disclosure.

### DESCRIPTION OF EMBODIMENTS

The processes for achieving embodiments of this disclosure are described below in detail in conjunction with the accompanying drawings. It is to be noted that the same or similar numerals represent the same or similar elements or elements having the same or similar functions throughout. The embodiments described below with reference to the accompanying drawings are exemplary and are merely used for explaining the present invention, and cannot be construed to be limitations of this invention.

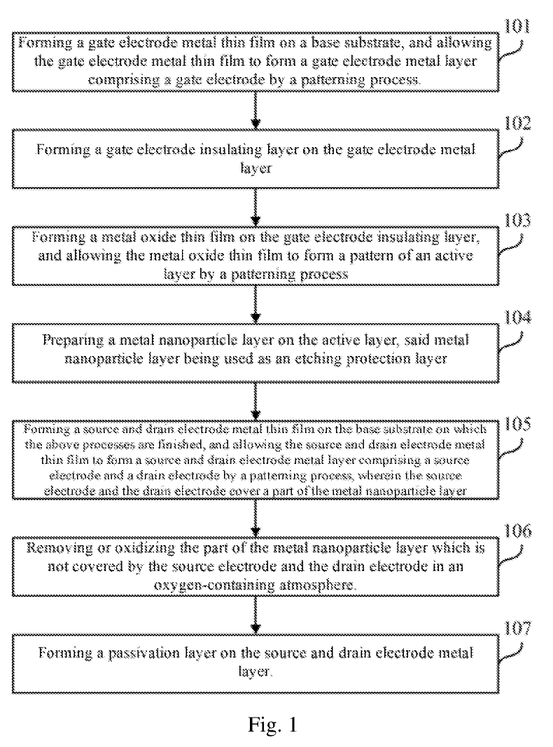

With reference to FIG. 1, an embodiment of this disclosure provides a preparation method of a thin film transistor, comprising:

101, forming a gate electrode metal thin film on a base substrate, and allowing the gate electrode metal thin film to form a gate electrode metal layer comprising a gate electrode by a patterning process.

According to different particular applications of the metal oxide thin film transistor, a glass substrate having a buffering layer may be used as the base substrate, and a flexible substrate having a water-oxygen barrier layer may also be used as the base substrate, preferably, polyethylene naphthalate, polyethylene terephthalate, a polyimide, or a metal foil is used as the material of the flexible substrate. Preferably, a SiO₂ buffering layer or a Si₃N₄ layer is used as the buffering layer on the glass substrate. Preferably, an Al₂O₃ layer, a Si₃N₄ layer, a SiCN layer, a SiOₓ layer, a SiON layer, and a stacked composite structure thereof may be used as the water-oxygen barrier layer.

Preferably, the gate electrode metal thin film is prepared by using a single film layer of any one of an aluminum thin film, a copper thin film, a molybdenum thin film, a titanium thin film, a silver thin film, a gold thin film, a tantalum thin film, a tungsten thin film, a chromium thin film, and an aluminum alloy thin film, or a composite film layer composed of at least two of the thin films, and the gate electrode metal thin film is prepared in a thickness of 100 to 2000 nanometers.

102, forming a gate electrode insulating layer on the gate electrode metal layer.

Preferably, the gate electrode insulating layer is prepared by using a monolayer of a silicon oxide thin film, a silicon nitride thin film, an aluminum oxide thin film, a tantalum pentoxide thin film, or an ytterbium oxide thin film, or the gate electrode insulating layer is prepared by using a composite thin film composed of at least two monolayers of the thin films, and the gate electrode insulating layer is prepared in a thickness of 50 to 500 nanometers.

103, forming a metal oxide thin film on the gate electrode insulating layer, and allowing the metal oxide thin film to form a pattern of an active layer by a patterning process.

Preferably, the active layer is prepared by using a metal oxide containing at least one of In, Zn, Ga, and Sn, and the active layer is prepared in a thickness of 10 to 200 nanometers.

104, preparing a metal nanoparticle layer on the active layer, said metal nanoparticle layer being used as an etching protection layer.

Specifically, the metal nanoparticle layer may be deposited by using a process such as a physical vapor deposition, a chemical vapor deposition, a hydrothermal method, a sol-gel method, a spray pyrolysis method, a hot wall method, etc.

The metal nanoparticle layer is prepared by using at least one material of gold nanoparticles, silver nanoparticles, platinum nanoparticles, beryllium nanoparticles, nickel nanoparticles, and cobalt nanoparticles. Preferably, the metal nanoparticle layer is prepared in a thickness of 1 to 5 nanometers. Of course, in view of cost, one or more of beryllium nanoparticles, nickel nanoparticles, and cobalt nanoparticles having lower cost may also be used for the metal nanoparticle layer.

It is to be indicated that after the metal nanoparticle layer is deposited, it may further comprise a process of performing annealing treatment on the metal nanoparticle layer.

In this embodiment, the active layer can be protected by the metal nanoparticle layer when the source electrode and the drain electrode are etched, so as to prevent device badness caused by the corrosion of the active layer.

105, forming a source and drain electrode metal thin film on the base substrate on which the above processes are finished, allowing the source and drain electrode metal thin film to form a source and drain electrode metal layer comprising a source electrode and a drain electrode by a patterning process, wherein the source electrode and the drain electrode cover a part of the metal nanoparticle layer.

Preferably, the source and drain electrode metal thin film is prepared by using a single film layer of any one of an aluminum thin film, a copper thin film, a molybdenum thin film, and a titanium thin film, or a composite film layer composed of at least two of the thin films, and the source and drain electrode metal thin film is prepared in a thickness of 100 to 2000 nanometers.

106, removing or oxidizing the part of the metal nanoparticle layer which is not covered by the source electrode and the drain electrode in an oxygen-containing atmosphere.

Preferably, removing or oxidizing the part of the metal nanoparticle layer which is not covered by the source electrode and the drain electrode is performed by using oxygen plasma.

107, forming a passivation layer on the source and drain electrode metal layer.

Preferably, the passivation layer is prepared by using a single film layer of any one of silicon oxide, silicon nitride, aluminum oxide, ytterbium oxide, polyimides, benzocyclobutene, and polymethyl methacrylate, or a composite film layer composed of at least two of silicon oxide, silicon nitride, aluminum oxide, ytterbium oxide, polyimides, benzocyclobutene, and polymethyl methacrylate, and the passivation layer is prepared in a thickness of 50 to 2000 nanometers.

It is to be indicated that a method for protecting the active layer by using an organic conductive thin film in a back channel etching process of a metal oxide thin film transistor is also provided in the prior art, but the conductivity of silicon or carbon in the organic conductive thin film is relatively poor, which may lead to bad contact of the active layer with the source electrode and the drain electrode, such that the metal oxide thin film transistor is instable; and at the meanwhile, the thermal stability of the organic conductive thin film is poor and will be decomposed in subsequent procedures, resulting in instable or bad metal oxide thin film transistors, and the decomposed organic conductive thin film may contaminate the preparation equipment. Compared to the organic conductive thin film, the metal nanoparticle layer has a better thermal stability, is capable of protecting the active layer, enables the metal oxide thin film transistor thus prepared to be more stable, and will not contaminate the preparation equipment.

The embodiments of this disclosure have the advantageous effects as follows. By using the metal nanoparticle layer as a protection layer of the active layer, the active layer can be protected when the source electrode and the drain electrode are etched, so as to prevent device badness caused by the corrosion of the active layer; and at the meanwhile, the metal nanoparticle layer has a good conductivity and is favorable to the achievement of good conductive contact with the source electrode and the drain electrode; the metal nanoparticle layer has a better thermal stability compared to the organic conductive thin film, and the requirements for the preparation process of the metal oxide thin film transistor are relatively low, such that the preparation of the metal oxide thin film transistor by a simple process and a low cost is achieved.

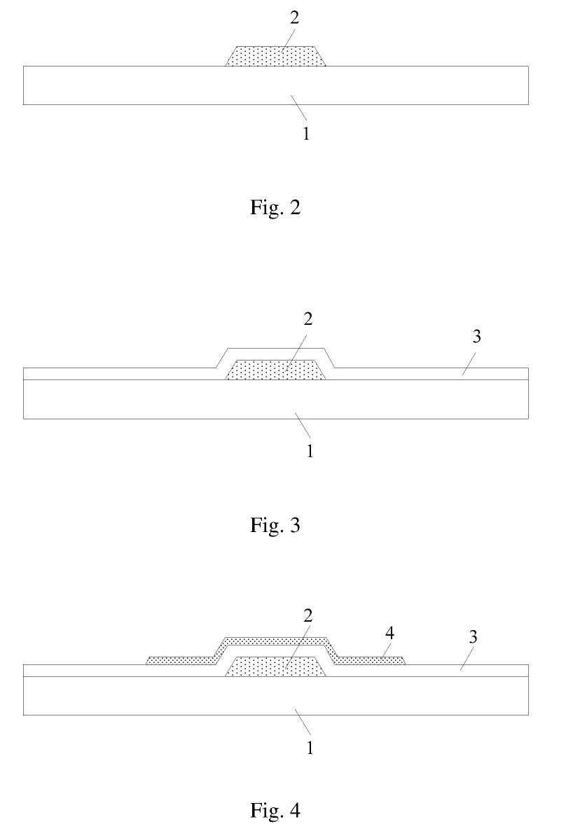

In order to describe the preparation method of the metal oxide thin film transistor provided by this disclosure in more detail, embodiments are provided in conjunction with FIG. 2 to FIG. 9 as follows.

### Embodiment 1

This embodiment of this disclosure provides a first particular preparation method of a metal oxide thin film transistor, comprising:

Step 1, depositing three layers of metal thin films of molybdenum/aluminum/molybdenum as a gate electrode metal thin film on a base substrate 1 by using a physical vapor deposition method, wherein the three layers of metal thin films of molybdenum/aluminum/molybdenum have thicknesses of 25/100/25 nanometers respectively, and allowing the gate electrode metal thin film to form a gate electrode 2 by a patterning process. The base substrate 1 is an alkali-free glass substrate with a SiO₂ buffering layer having a thickness of 200 nanometers. The schematic diagram after the gate electrode 2 is prepared on the base substrate 1 is shown in FIG. 2.

Step 2, depositing a gate electrode insulating layer 3 by using a plasma enhanced chemical vapor deposition method, on the base substrate 1 on which the above step is finished. The schematic diagram after the gate electrode insulating layer 3 is prepared is shown in FIG. 3.

The gate electrode insulating layer 3 is formed by laminating 300-nanometer SiNₓ and 30-nanometer SiO₂.

Step 3, depositing a metal oxide thin film on the gate electrode insulating layer 3 by using a physical vapor deposition method, and allowing the metal oxide thin film to form a pattern of an active layer 4 by a patterning process. The metal oxide thin film is an indium zinc oxide (IZO) thin film, wherein the atomic ratio of indium to zinc is 1:1. The schematic diagram in which the active layer 4 is prepared is shown in FIG. 4.

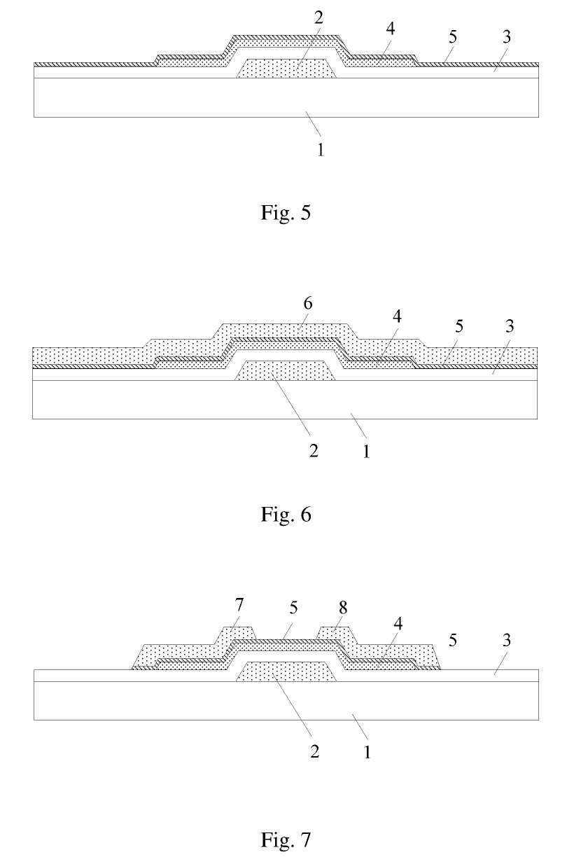

Step 4, depositing a gold nanoparticle layer having a thickness of 5 nanometers as a metal nanoparticle layer 5 on the active layer 4 by using a physical vapor deposition method. The schematic diagram in which the metal nanoparticle layer 5 is prepared is shown in FIG. 5.

The active layer 4 can be protected by the metal nanoparticle layer 5 when the source electrode 7 and the drain electrode 8 (as shown in FIG. 7) are subsequently etched, so as to prevent the badness of the metal oxide thin film transistor caused by the corrosion of the active layer 4.

It is to be indicated that it may further comprise a process of annealing the metal nanoparticle layer 5 in Step 4.

Step 5, depositing laminated layers of molybdenum/aluminum/molybdenum, which have thicknesses of 25/100/25 nanometers respectively, as a source and drain electrode metal thin film 6 on the base substrate 1 on which the above processes are finished, by using a physical vapor deposition method. The schematic diagram in which the source and drain electrode metal thin film 6 is prepared is shown in FIG. 6.

A mixed solution of 30% H₂O₂ and 1% KOH is used as a wet etching solution for etching the source and drain electrode metal thin film 6 to form a source electrode 7 and a drain electrode 8, wherein the source electrode 7 and the drain electrode 8 cover a part of the metal nanoparticle layer 5. The schematic diagram in which the source electrode 7 and the drain electrode 8 are prepared is shown in FIG. 7.

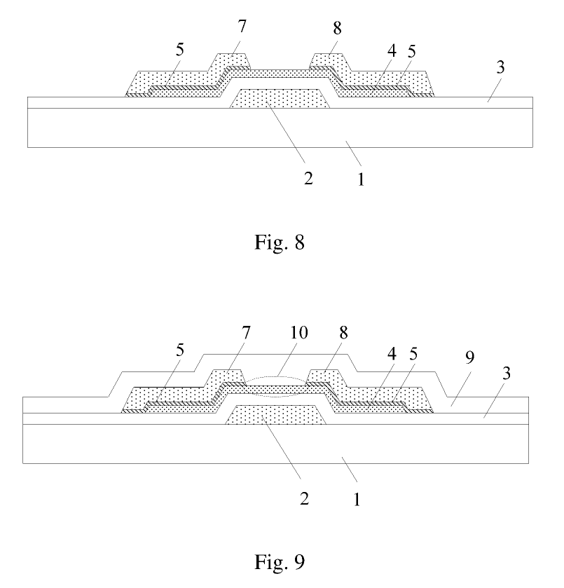

Step 6, removing the part of the metal nanoparticle layer 5 which is not covered by the source electrode 7 and the drain electrode 8 by using oxygen plasma. The schematic diagram after the part of the metal nanoparticle layer 5 not covered by the source electrode 7 and the drain electrode 8 is removed is shown in FIG. 8.

Step 7, depositing 300-nanometer SiO₂ as a passivation layer 9 on the base substrate 1 on which the above processes are finished, by using a plasma enhanced chemical vapor deposition method, i.e., forming a passivation layer 9 on the source and drain electrode metal layer comprising the source electrode 7 and the drain electrode 8. The schematic diagram in which the passivation layer 9 is prepared is shown in FIG. 9.

It is practically found that the protection of the active layer 4 in the back channel etching process by using the metal nanoparticle layer 5 is more stable compared to the protection by an organic conductive thin film, and the metal nanoparticle layer 5 has a good conductivity, large surface roughness, and is very favorable to the achievement of good contact of the active layer 4 with the source electrode 7 and the drain electrode 8.

### Embodiment 2

This embodiment of this disclosure provides a second particular preparation method of a metal oxide thin film transistor, comprising:

Step 1, depositing a copper metal thin film as a gate electrode metal thin film on a base substrate 1 by using a physical vapor deposition method, wherein the copper metal thin film has a thickness of 500 nanometers, and allowing the gate electrode metal thin film to form a gate electrode 2 by a patterning process. The base substrate 1 is a flexible substrate with a water-oxygen barrier layer of Al₂O₃ having a thickness of 50 nanometers. The schematic diagram after the gate electrode 2 is prepared on the base substrate 1 is shown in FIG. 2.

Step 2, depositing a gate electrode insulating layer 3 by using a plasma enhanced chemical vapor deposition method, on the base substrate 1 on which the above step is finished. The schematic diagram after the gate electrode insulating layer 3 is prepared is shown in FIG. 3.

The gate electrode insulating layer 3 is formed by laminating 200-nanometer aluminum oxide and 100-nanometer ytterbium oxide.

Step 3, depositing a metal oxide thin film on the gate electrode insulating layer 3 by using a physical vapor deposition method, and allowing the metal oxide thin film to form a pattern of an active layer 4 by a patterning process. The metal oxide thin film is an 80-nanometer indium gallium zinc oxide (IGZO) thin film, wherein the atomic ratio of indium, gallium, and zinc is 1:1:1. The schematic diagram in which the active layer 4 is prepared is shown in FIG. 4.

Step 4, preparing a nickel nanoparticle layer having a thickness of 2 nanometers as a metal nanoparticle layer 5 on the active layer 4, by using a spray pyrolysis method. The schematic diagram in which the metal nanoparticle layer 5 is prepared is shown in FIG. 5.

The active layer 4 can be protected by the metal nanoparticle layer 5 when the source electrode 7 and the drain electrode 8 (as shown in FIG. 7) are subsequently etched, so as to prevent the badness of the metal oxide thin film transistor caused by the corrosion of the active layer 4.

It is to be indicated that it may further comprise a process of annealing the metal nanoparticle layer 5 in Step 4.

Step 5, depositing a copper metal thin film having a thicknesses of 500 nanometers as a source and drain electrode metal thin film 6 on the base substrate 1 on which the above processes are finished, by using a physical vapor deposition method. The schematic diagram in which the source and drain electrode metal thin film 6 is prepared is shown in FIG. 6.

A mixed solution of H₂O₂ and H₂SO₄ is used as a wet etching solution for etching the source and drain electrode metal thin film 6 to form a source electrode 7 and a drain electrode 8, wherein the source electrode 7 and the drain electrode 8 cover a part of the metal nanoparticle layer 5. The schematic diagram in which the source electrode 7 and the drain electrode 8 are prepared is shown in FIG. 7.

Step 6, removing the part of the metal nanoparticle layer 5 which is not covered by the source electrode 7 and the drain electrode 8 by using oxygen plasma. The schematic diagram after the part of the metal nanoparticle layer 5 not covered by the source electrode 7 and the drain electrode 8 is removed is shown in FIG. 8.

Step 7, depositing 800-nanometer polyimide as a passivation layer 9 on the base substrate 1 on which the above processes are finished, by using a plasma enhanced chemical vapor deposition method, i.e., forming a passivation layer 9 on the source and drain electrode metal layer comprising the source electrode 7 and the drain electrode 8. The schematic diagram in which the passivation layer 9 is prepared is shown in FIG. 9.

It is practically found that the protection of the active layer 4 in the back channel etching process by using the metal nanoparticle layer 5 is more stable compared to the protection by an organic conductive thin film, and the metal nanoparticle layer has a good conductivity, a rough surface, and is very favorable to the achievement of good contact of the active layer 4 with the source electrode 7 and the drain electrode 8.

### Embodiment 3

This embodiment of this disclosure provides a third particular preparation method of a metal oxide thin film transistor, comprising:

Step 1, depositing an ITO thin film as a gate electrode metal thin film on a base substrate 1 by using a physical vapor deposition method, wherein the ITO thin film has a thickness of 200 nanometers, and allowing the gate electrode metal thin film to form a gate electrode 2 by a patterning process. The base substrate 1 is a flexible substrate with a water-oxygen barrier layer of Si₃N₄ having a thickness of 200 nanometers. The schematic diagram after the gate electrode 2 is prepared on the base substrate 1 is shown in FIG. 2.

Step 2, depositing a gate electrode insulating layer 3 by using a plasma enhanced chemical vapor deposition method on the base substrate 1 on which the above step is finished. The schematic diagram after the gate electrode insulating layer 3 is prepared is shown in FIG. 3.

The gate electrode insulating layer 3 is formed by laminating 100-nanometer silicon oxide, 90-nanometer tantalum pentoxide, and 20-nanometer silicon dioxide.

Step 3, depositing a metal oxide thin film on the gate electrode insulating layer 3 by using a physical vapor deposition method, and allowing the metal oxide thin film to form a pattern of an active layer 4 by a patterning process. The metal oxide thin film is a 50-nanometer IZO thin film, wherein the atomic ratio of indium to zinc is 1:1. The schematic diagram in which the active layer 4 is prepared is shown in FIG. 4.

Step 4, preparing a silver nanoparticle layer having a thickness of 3 nanometers as a metal nanoparticle layer 5 on the active layer 4 by using a solution treatment method. The schematic diagram in which the metal nanoparticle layer 5 is prepared is shown in FIG. 5.

The active layer 4 can be protected by the metal nanoparticle layer 5 when the source electrode 7 and the drain electrode 8 (as shown in FIG. 7) are subsequently etched, so as to prevent the badness of the metal oxide thin film transistor caused by the corrosion of the active layer 4.

It is to be indicated that it may further comprise a process of annealing the metal nanoparticle layer 5 in Step 4.

Step 5, depositing a copper metal thin film, which is a monolayer molybdenum thin film and has a thicknesses of 200 nanometers, as a source and drain electrode metal thin film 6 on the base substrate 1 on which the above processes are finished, by using a physical vapor deposition method. The schematic diagram in which the source and drain electrode metal thin film 6 is prepared is shown in FIG. 6.

A mixed solution of H₂O₂ and H₂SO₄ is used as a wet etching solution for etching the source and drain electrode metal thin film 6 to form a source electrode 7 and a drain electrode 8, wherein the source electrode 7 and the drain electrode 8 cover a part of the metal nanoparticle layer 5. The schematic diagram in which the source electrode 7 and the drain electrode 8 are prepared is shown in FIG. 7.

Step 6, removing the part of the metal nanoparticle layer 5 which is not covered by the source electrode 7 and the drain electrode 8 by using oxygen plasma. The schematic diagram after the part of the metal nanoparticle layer 5 not covered by the source electrode 7 and the drain electrode 8 is removed is shown in FIG. 8.

Step 7, depositing 300-nanometer SiO₂ as a passivation layer 9 on the base substrate 1 on which the above processes are finished, by using a plasma enhanced chemical vapor deposition method, i.e., forming a passivation layer 9 on the source and drain electrode metal layer comprising the source electrode 7 and the drain electrode 8. The schematic diagram in which the passivation layer 9 is prepared is shown in FIG. 9.

It is practically found that the protection of the active layer 4 in the back channel etching process by using the metal nanoparticle layer 5 is more stable compared to the protection by an organic conductive thin film, and the metal nanoparticle layer has a good conductivity, a rough surface, and is very favorable to the achievement of good contact of the active layer 4 with the source electrode 7 and the drain electrode 8.

The above embodiments 1 to 3 are merely a part of specific embodiments provided to illustrate this disclosure, and this disclosure is not limited thereto. The prepared metal oxide thin film transistors may be used in liquid crystal displays and active matrix organic light-emitting diode displays. Thicknesses of thin films, constituent materials, proportioning ratios, etc., involved in each step in embodiments 1 to 3 may be adjusted according to practical requirements.

As shown in FIG. 9, one embodiment of this disclosure further provides a thin film transistor, which is a metal oxide thin film transistor, comprising:

a base substrate 1;

a gate electrode metal layer formed on the base substrate 1, wherein the gate electrode metal layer comprises a gate electrode 2;

a gate electrode insulating layer 3 formed on the gate electrode metal layer;

an active layer 4 formed on the gate electrode insulating layer;

a metal nanoparticle layer 5 formed on the active layer 4, wherein the metal nanoparticle layer 5 is used as an etching protection layer;

a source and drain electrode metal layer formed on the metal nanoparticle layer 5, wherein the source and drain electrode metal layer comprises a source electrode 7 and a drain electrode 8; and

a passivation layer 9 formed on the source and drain electrode metal layer.

It is to be indicated that the part indicated by the dashed frame 10 is the removed part of metal nanoparticle layer 5, which is removed after the source electrode 7 and the drain electrode 8 are formed. This part of the metal nanoparticle layer 5, which should be removed, can protect the active layer 4 when the source electrode 7 and the drain electrode 8 are prepared.

Preferably, the metal nanoparticle layer 5 comprises at least one material of gold nanoparticles, silver nanoparticles, platinum nanoparticles, beryllium nanoparticles, nickel nanoparticles, and cobalt nanoparticles.

Preferably, the metal nanoparticle layer 5 has a thickness of 1 to 5 nanometers.

Preferably, the base substrate 1 is a glass substrate having a buffering layer.

Preferably, the base substrate 1 is a flexible substrate having a water-oxygen barrier layer, and the material of the flexible substrate is polyethylene naphthalate, polyethylene terephthalate, a polyimide, or a metal foil.

Preferably, the gate electrode metal layer is a single film layer of any one of an aluminum thin film, a copper thin film, a molybdenum thin film, a titanium thin film, a silver thin film, a gold thin film, a tantalum thin film, a tungsten thin film, a chromium thin film, and an aluminum alloy thin film, or a composite film layer composed of at least two of the thin films, and the gate electrode metal layer has a thickness of 100 to 2000 nanometers. It is to be indicated that the material and the thickness of the gate electrode metal layer herein are those of the gate electrode metal thin film in the preparation method.

Preferably, the gate electrode insulating layer 3 is a monolayer of a silicon oxide thin film, a silicon nitride thin film, an aluminum oxide thin film, a tantalum pentoxide thin film, or an ytterbium oxide thin film, or the gate electrode insulating layer 3 is a composite thin film composed of at least two monolayers of the thin films, and the gate electrode insulating layer 3 has a thickness of 50 to 500 nanometer.

Preferably, the active layer 4 contains a metal oxide of at least one of In, Zn, Ga, and Sn, the active layer 4 has a thickness of 10 to 200 nanometers.

Preferably, the source and drain electrode metal layer is a single film layer of any one of an aluminum thin film, a copper thin film, a molybdenum thin film, and a titanium thin film, or a composite film layer composed of at least two of the thin films, the source and drain electrode metal layer has a thickness of 100 to 2000 nanometers. It is to be indicated that the material and the thickness of the source and drain electrode metal layer herein are those of the source and drain electrode metal thin film in the preparation method.

Preferably, the passivation layer 9 may be a single film layer of any one of silicon oxide, silicon nitride, aluminum oxide, ytterbium oxide, polyimides, benzocyclobutene, and polymethyl methacrylate, or a composite film layer composed of at least two of silicon oxide, silicon nitride, aluminum oxide, ytterbium oxide, polyimides, benzocyclobutene, and polymethyl methacrylate. Preferably, the passivation layer 9 has a thickness of 50 to 2000 nanometers.

The embodiment of this disclosure has the advantageous effects as follows. By using the metal nanoparticle layer as a protection layer of the active layer, the active layer can be protected when the source electrode and the drain electrode are etched, so as to prevent device badness caused by the corrosion of the active layer; and at the meanwhile, the metal nanoparticle layer has a good conductivity and good thermal stability, and the requirements for the preparation process of the metal oxide thin film transistor are relatively low, such that the preparation of the metal oxide thin film transistor by a simple process and a low cost is achieved.

Based on the same inventive concept, one embodiment of this disclosure further provides an array substrate, comprising the thin film transistor as provided by the above embodiment.

The embodiment of this disclosure has the advantageous effects as follows. In this array substrate, the metal oxide thin film transistor uses the metal nanoparticle layer as a protection layer of the active layer, and the active layer can be protected when the source electrode and the drain electrode are etched, so as to prevent device badness caused by the corrosion of the active layer; and at the meanwhile, the metal nanoparticle layer has a good conductivity and good thermal stability, and the requirements for the preparation process of the metal oxide thin film transistor are relatively low, such that the preparation of the metal oxide thin film transistor by a simple process and a low cost is achieved.

Based on the same inventive concept, one embodiment of this disclosure provides a display panel, comprising the array substrate as provided by the above embodiment.

The embodiment of this disclosure has the advantageous effects as follows. In the array substrate used by the display panel, the metal oxide thin film transistor uses the metal nanoparticle layer as a protection layer of the active layer, and the active layer can be protected when the source electrode and the drain electrode are etched, so as to prevent device badness caused by the corrosion of the active layer; and at the meanwhile, the metal nanoparticle layer has a good conductivity and good thermal stability, and the requirements for the preparation process of the metal oxide thin film transistor are relatively low, such that the preparation of the metal oxide thin film transistor by a simple process and a low cost is achieved.

Obviously, a person skilled in the art may perform various modifications and variations on this invention without departing from the spirit and the scope of this invention. Thus, if these modifications and variations of the invention are within the scope of the claims of this application and equivalent techniques thereof, this invention also intends to encompass these modifications and variations.

1. A preparation method of a thin film transistor, comprising:
forming a gate electrode metal thin film on a base substrate, and allowing the gate electrode metal thin film to form a gate electrode metal layer comprising a gate electrode by a patterning process;
forming a gate electrode insulating layer on the gate electrode metal layer;
forming a metal oxide thin film on the gate electrode insulating layer, and allowing the metal oxide thin film to form a pattern of an active layer by a patterning process;
preparing a metal nanoparticle layer on the active layer, said metal nanoparticle layer being used as an etching protection layer;
forming a source and drain electrode metal thin film on the base substrate on which the above processes are finished, and allowing the source and drain electrode metal thin film to form a source and drain electrode metal layer comprising a source electrode and a drain electrode by a patterning process, wherein the source electrode and the drain electrode cover a part of the metal nanoparticle layer;
removing or oxidizing the part of the metal nanoparticle layer which is not covered by the source electrode and the drain electrode in an oxygen-containing atmosphere; and
forming a passivation layer on the source and drain electrode metal layer.

2. The preparation method as claimed in claim 1, wherein the metal nanoparticle layer is prepared by using at least one material of gold nanoparticles, silver nanoparticles, platinum nanoparticles, beryllium nanoparticles, nickel nanoparticles, and cobalt nanoparticles.

3. The preparation method as claimed in claim 2, wherein preparing the metal nanoparticle layer on the active layer comprises:
preparing the metal nanoparticle layer on the active layer by using a physical vapor deposition, a chemical vapor deposition, a hydrothermal method, a sol-gel method, a spray pyrolysis method, or a hot wall method.

4. The preparation method as claimed in claim 2, wherein the metal nanoparticle layer is prepared in a thickness of 1 to 5 nanometers.

5. The preparation method as claimed in claim 1, wherein a glass substrate having a buffering layer is used as the base substrate.

6. The preparation method as claimed in claim 1, wherein a flexible substrate having a water-oxygen barrier layer is used as the base substrate, and polyethylene naphthalate, polyethylene terephthalate, a polyimide, or a metal foil is used as the material of the flexible substrate.

7. The preparation method as claimed in claim 1, wherein the gate electrode metal thin film is prepared by using a single film layer of any one of an aluminum thin film, a copper thin film, a molybdenum thin film, a titanium thin film, a silver thin film, a gold thin film, a tantalum thin film, a tungsten thin film, a chromium thin film, and an aluminum alloy thin film, or a composite film layer composed of at least two of the thin films, and the gate electrode metal thin film is prepared in a thickness of 100 to 2000 nanometers.

8. The preparation method as claimed in claim 1, wherein the gate electrode insulating layer is prepared by using a monolayer of a silicon oxide thin film, a silicon nitride thin film, an aluminum oxide thin film, a tantalum pentoxide thin film, or an ytterbium oxide thin film, or the gate electrode insulating layer is prepared by using a composite thin film composed of at least two monolayers of the thin films, and the gate electrode insulating layer is prepared in a thickness of 50 to 500 nanometers.

9. The preparation method as claimed in claim 1, wherein the active layer is prepared by using a metal oxide containing at least one of In, Zn, Ga, and Sn, and the active layer is prepared in a thickness of 10 to 200 nanometers.

10. The preparation method as claimed in claim 1, wherein the source and drain electrode metal thin film is prepared by using a single film layer of any one of an aluminum thin film, a copper thin film, a molybdenum thin film, and a titanium thin film, or a composite film layer composed of at least two of the thin films, and the source and drain electrode metal thin film is prepared in a thickness of 100 to 2000 nanometers.

11. The preparation method as claimed in claim 1, wherein removing or oxidizing the part of the metal nanoparticle layer which is not covered by the source electrode and the drain electrode is performed by using oxygen plasma.

12. The preparation method as claimed in claim 1, wherein the passivation layer is prepared by using a single film layer of any one of silicon oxide, silicon nitride, aluminum oxide, ytterbium oxide, polyimide, benzocyclobutene, and polymethyl methacrylate, or a composite film layer composed of at least two of silicon oxide, silicon nitride, aluminum oxide, ytterbium oxide, polyimide, benzocyclobutene, and polymethyl methacrylate, and the passivation layer is prepared in a thickness of 50 to 2000 nanometers.

13. A thin film transistor, comprising:
a base substrate;
a gate electrode metal layer formed on the base substrate, wherein the gate electrode metal layer comprises a gate electrode;
a gate electrode insulating layer formed on the gate electrode metal layer;
an active layer formed on the gate electrode insulating layer;
a metal nanoparticle layer formed on the active layer, wherein the metal nanoparticle layer is used as an etching protection layer;
a source and drain electrode metal layer formed on the metal nanoparticle layer, wherein the source and drain electrode metal layer comprises a source electrode and a drain electrode; and
a passivation layer formed on the source and drain electrode metal layer.

14. An array substrate, comprising the thin film transistor as claimed in claim 13.

15. A display panel, comprising an array substrate according to claim 14.

16. The preparation method as claimed in claim 1, wherein after the metal nanoparticle layer is deposited, the method further comprises performing annealing treatment on the metal nanoparticle layer.

17. A thin film transistor prepared by the preparation method of claim 1, the thin film transistor comprising:
a base substrate;
a gate electrode metal layer formed on the base substrate, wherein the gate electrode metal layer comprises a gate electrode;
a gate electrode insulating layer formed on the gate electrode metal layer;
an active layer formed on the gate electrode insulating layer;
a metal nanoparticle layer formed on the active layer, wherein the metal nanoparticle layer is used as an etching protection layer;
a source and drain electrode metal layer formed on the metal nanoparticle layer, wherein the source and drain electrode metal layer comprises a source electrode and a drain electrode; and
a passivation layer formed on the source and drain electrode metal layer.
